(19) United States
(12) Patent Application Publication
(10) Pub. No.: US 2013/0010880 A1
(43) Pub. Date: Jan. 10, 2013

(54) Feedback Framework for MIMO Operation in Heterogeneous Communication Network

(75) Inventors: Tommi Koivisto, Espoo (FI); Mihai Enescu, Espoo (FI); Timo Roman, Espoo (FI); Karol Schober, Helsinki (FI)

(73) Assignee: Renesas Mobile Corporation, Tokyo (JP)

(21) Appl. No.: 13/176,169

(22) Filed: Jul. 5, 2011

(51) Int. Cl. H04L 27/00; H03D 1/00

(52) U.S. Cl. 375/259; 375/340

(57) ABSTRACT

There is provided a mechanism providing a flexible feedback framework operating in different scenarios, such as heterogeneous network deployments. Antenna information are sent from a scheduler element to a UE, the antenna information including information indicating a grouping of one or more antenna in closely spaced antenna groups of one or more transmit points. The UE selects at least one of precoding codewords and amplitude weight parameters for each closely spaced antenna group, and determines information related to a sub-band precoder and a transmit point related combiner. The processing results are indicated to the scheduler by means of sending indices related to a wide-band long-term precoder and a sub-band short-term precoder. The scheduler processes these results for determining a joint precoder.

### BACKGROUND OF THE INVENTION

1. Field of the Invention

The present invention relates to a feedback framework for MIMO operation in heterogeneous networks. In particular, the present invention is related to apparatuses, methods and computer program products providing a mechanism by means of which a feedback framework supporting MIMO operation in heterogeneous networks with single or multiple cell IDs in addition to a normal single transmission point operation is achievable.

2. Related Background Art

Prior art which is related to this technical field can e.g. be found by the technical specification 3GPP TS 36.211, for example according to version 10.1.0.

The following meanings for the abbreviations used in this specification apply:

BS base station
CB codebook
CoMP coordinated multipoint transmission
CQI channel quality indication
CRS common reference signal
CSAG closely spaced antenna group
CSI channel state information
CSI-RS channel state information—reference signal
DFT discrete Fourier transform

### DL Downlink

eNB enhanced Node B
HetNet heterogeneous network
RRH remote radio head
RRM radio resource management
ID identification

### LTE Long Term Evolution

### LTE-A LTE Advanced

MIMO multiple input multiple output
MU-MIMO multiple user MIMO
PMI precoding matrix indicator
SU-MIMO single user MIMO
RF radio frequency
RRH remote radio head
RRM radio resource management
Tx transmission
UE user equipment
UL uplink
ULA uniform linear array
XP cross polarized array

In the last years, an increasing extension of communication networks, e.g. of wire based communication networks, such as the Integrated Services Digital Network (ISDN), DSL, or wireless communication networks, such as the cdma2000 (code division multiple access) system, cellular 3rd generation (3G) communication networks like the Universal Mobile Telecommunications System (UMTS), enhanced communication networks based e.g. on LTE, cellular 2nd generation (2G) communication networks like the Global System for Mobile communications (GSM), the General Packet Radio System (GPRS), the Enhanced Data Rates for Global Evolutions (EDGE), or other wireless communication system, such as the Wireless Local Area Network (WLAN), Bluetooth or Worldwide Interoperability for Microwave Access (WiMAX), took place all over the world. Various organizations, such as the 3rd Generation Partnership Project (3GPP), Telecoms & Internet converged Services & Protocols for Advanced Networks (TISPAN), the International Telecommunication Union (ITU), 3rd Generation Partnership Project 2 (3GPP2), Internet Engineering Task Force (IETF), the IEEE (Institute of Electrical and Electronics Engineers), the WiMAX Forum and the like are working on standards for telecommunication network and access environments. Examples for new communication technologies are for example LTE and LTE-A of 3GPP.

Some important features for new communication systems like LTE or LTE-A based networks are related to DL and UL MIMO, relays, bandwidth extension via carrier aggregation and enhanced inter-cell interference coordination (eICIC).

For example, when comparing Release 10 LTE systems with former Release 8/9 systems, related to DL MIMO, in order to meet peak spectral efficiency requirements of up to 30 bit/s/Hz, Release 10 extends Release 8/9 DL MIMO features by providing support for up to 8 stream transmission, and hence up to 8×8 MIMO, in contrast to 4 stream transmission supported by Release 8/9. Furthermore, enhanced support of MU MIMO is enabled, while Release 10 supports seamless switching between single- and multi-user operation.

One component of Release 10 is a so-called 8 Tx double codebook. This is based on a modular (or multi-granular) design, combining two feedback components from distinct codebooks: one feedback component represents the long-term (e.g. wideband) radio channel properties while the other one targets the short term (e.g. frequency selective) channel properties.

In future systems, like e.g. 3GPP LTE Release 11, one ongoing study item targets to further DL MIMO enhancements. For example, it is intended to provide scenarios which use several features like low-power nodes (including indoor), relay backhaul, separated antenna configurations including geographically separated antennas, that is a macro-node like a BS or eNB with several connected low-power remote radio heads (RRHs).

However, in order to enable such scenarios to work, it is necessary to provide a suitable feedback framework. This invention deals with codebook design for the scenario including a macro-node with low power RRHs (or more generically distributed antennas). We propose a new feedback framework which has the required flexibility to operate in heterogeneous network deployments.

### SUMMARY OF THE INVENTION

It is an object of the invention to provide feedback framework having a high flexibility to operate in different scenarios, such as heterogeneous network deployments. In particular, it is an object of the present invention to provide an apparatus, method and computer program product by means of which a unified feedback framework is provided which supports heterogeneous networks with single/multiple cell IDs in addition to normal single transmission point operation. Specifically, according to the present invention, it is intended to provide a codebook design for a scenario including a macro-node with low power RRHs (or more generically distributed antennas).

These objects are achieved by the measures defined in the attached claims.

According to an example of an embodiment of the proposed solution, there is provided, for example, an apparatus comprising a receiver configured to receive antenna information, the antenna information comprising information indicating a grouping of one or more antenna in at least one closely spaced antenna group of one or more transmit points, an estimating processing portion configured to estimate channels based on the received antenna information, a selecting processing portion configured to select at least one of a precoding codeword and an amplitude weight parameter for each of the at least one closely spaced antenna group, a determining processing portion configured to determine information related to at least one of a sub-band precoder and a transmit point related combiner, and a reporting processing portion configured to report processing results of the selecting processing portion and the determining processing portion.

Furthermore, according to an example of an embodiment of the proposed solution, there is provided, for example, a method comprising receiving antenna information, the antenna information comprising information indicating a grouping of one or more antenna in at least one closely spaced antenna group of one or more transmit points, estimating channels based on the received antenna port configuration data, selecting at least one of a precoding codeword and an amplitude weight parameter for each of the at least one closely spaced antenna group, determining information related to at least one of a sub-band precoder and a transmit point related combiner, and reporting results of the selecting and the determining.

Moreover, according to an example of an embodiment of the proposed solution, there is provided, for example, an apparatus comprising a signaling processing portion configured to initiate transmission of antenna information to a communication network element, the antenna information comprising information indicating a grouping of one or more antenna in at least one closely spaced antenna group of one or more transmit points, a receiving processing portion configured to receive processing results from the communication network element, the processing results comprising at least one of an index of precoding codewords and an index of an amplitude weight parameter for each of the at least one closely spaced antenna group, and at least one of an index of a sub-band precoder and an index of a transmit point related combiner, and a processing portion configured to process the received processing results and to compute a final precoder on the basis the received processing results.

In addition, according to examples of the proposed solution, there is provided, for example, a computer program product for a computer, comprising software code portions for performing the steps of the above defined methods, when said product is run on the computer. The computer program product may comprise a computer-readable medium on which said software code portions are stored. Furthermore, the computer program product may be directly loadable into the internal memory of the computer and/or transmittable via a network by means of at least one of upload, download and push procedures.

By virtue of the proposed solutions, it is possible to provide a unified feedback framework that supports heterogeneous networks with single/multiple cell IDs in addition to normal single transmission point operation. Specifically, according to the present invention, a CSI feedback operating in a macro-node and low power RRH scenario supporting both SU and MU MIMO is provided, wherein the proposed feedback framework provides sufficient flexibility so that various combinations of number of closely spaced antenna groups (CSAGs), each consisting of various numbers of transmit antennas are possible.

Furthermore, a codebook and a creation thereof is proposed which has a structure designed for example for use with heterogeneous networks, where multiple transmission points are participating in the transmission, but which is also applicable for “normal” single transmission point transmission, for example single-cell transmission. Examples of embodiments of the invention are also applicable to scenarios with single transmission point having widely spaced antennas wherein in such a case the codebook may consist e.g. of two closely-spaced antenna groups and the related intra-transmission point combiners.

The above and still further objects, features and advantages of the invention will become more apparent upon referring to the description and the accompanying drawings.

### BRIEF DESCRIPTION OF THE DRAWINGS

FIG. 1 shows a diagram illustrating a scenario of a network having a macro-node and low-power RRHs where examples of embodiments of the invention are applicable.

FIG. 2 shows a signaling diagram illustrating a procedure for computing a precoder based on a feedback framework according to an example of embodiments of the invention.

FIG. 3 shows a flowchart illustrating a processing executed in a communication network control element like a base station or eNB in a procedure according to an example of embodiments of the invention.

FIG. 4 shows a flowchart illustrating a processing executed in a communication network element like a UE in a procedure according to an example of embodiments of the invention.

FIG. 5 shows a block circuit diagram of a communication network control element including processing portions conducting functions according to examples of embodiments of the invention.

FIG. 6 shows a block circuit diagram of a communication network element including processing portions conducting functions according to examples of embodiments of the invention.

### DESCRIPTION OF PREFERRED EMBODIMENTS

In the following, examples and embodiments of the present invention are described with reference to the drawings. For illustrating the present invention, the examples and embodiments will be described in connection with a cellular communication network based on a 3GPP LTE system. However, it is to be noted that the present invention is not limited to an application using such types of communication system, but is also applicable in other types of communication systems and the like.

A basic system architecture of a communication network may comprise a commonly known architecture of a communication system comprising a wired or wireless access network subsystem and a core network. Such an architecture may comprise one or more access network control elements, radio access network elements, access service network gateways or base transceiver stations, such as a base station (BS) or eNB, with which a communication network element or device such as a UE or another device having a similar function, such as a modem chipset, a chip, a module etc., which can also be part of a UE or attached as a separate element to a UE, or the like, is capable to communicate via one or more channels for transmitting several types of data. Furthermore, core network elements such as gateway network elements, policy and charging control network elements, mobility management entities and the like are usually comprised.

The general functions and interconnections of the described elements, depending on the actual network type, are known to those skilled in the art and described in corresponding specifications so that a detailed description thereof is omitted herein. However, it is to be noted that several additional network elements and signaling links may be employed for a communication connection to or from UEs or eNBs, besides those described in detail herein below.

Furthermore, the described network elements, such as communication network elements like UEs or communication network control elements like BSs or eNBs, and the like, as well as corresponding functions as described herein may be implemented by software, e.g. by a computer program product for a computer, and/or by hardware. In any case, for executing their respective functions, correspondingly used devices, nodes or network elements may comprise several means and components (not shown) which are required for control, processing and communication/signaling functionality. Such means may comprise, for example, one or more processor units including one or more processing portions for executing instructions, programs and for processing data, memory means for storing instructions, programs and data, for serving as a work area of the processor or processing portion and the like (e.g. ROM, RAM, EEPROM, and the like), input means for inputting data and instructions by software (e.g. floppy diskette, CD-ROM, EEPROM, and the like), user interface means for providing monitor and manipulation possibilities to a user (e.g. a screen, a keyboard and the like), interface means for establishing links and/or connections under the control of the processor unit or portion (e.g. wired and wireless interface means, an antenna, etc.) and the like. It is to be noted that in the present specification processing portions should not be only considered to represent physical portions of one or more processors, but may also be considered as a logical division of the referred processing tasks performed by one or more processors.

Examples of embodiments of the invention are applicable to so-called heterogeneous networks. Generally, heterogeneous networks or HetNets, also known as non-uniform network deployments, represent a scenario which is considered in recent communication networks/deployments. For example, in LTE, HetNets originate from Release 10 where pico/femto cells are utilized in macro cells. In such a scenario, HetNets are considered within the context of enhanced inter-cell interference coordination/cancellation (eICIC), for example in connection with a macro-node, such as an eNB covering a (macro) cell, and pico/femto nodes deployed inside the macro cell. In LTE Release 11 based networks, HetNets are considered to be used for DL MIMO and coordinated multi-point transmission (CoMP), but also for single cell MIMO enhancements.

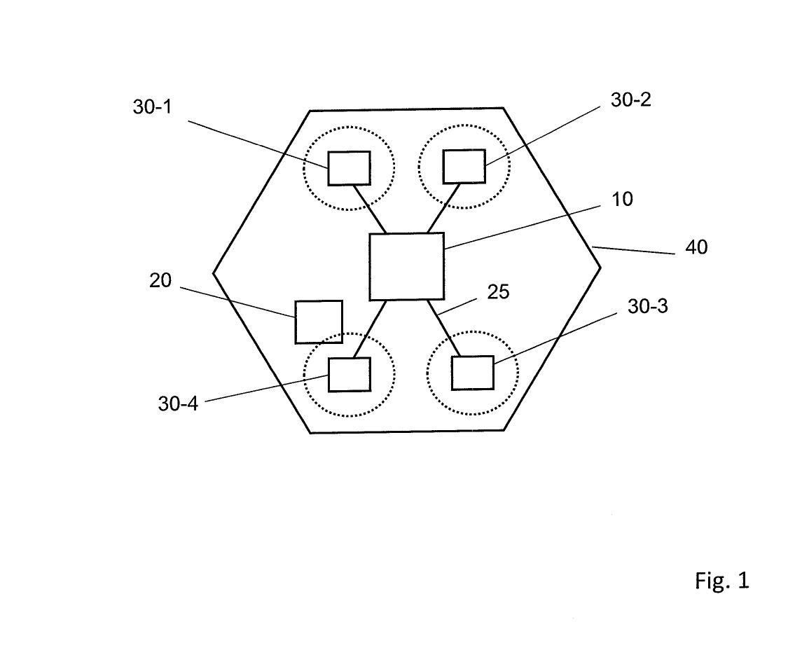

FIG. 1 shows a diagram illustrating a scenario of a network having a macro node controlled by a communication network control element such as an eNB of an LTE based cellular communication network, which is a control element for a specific area 40, also referred to as a cell, and four low-power RRHs 30-1, 30-2, 30-3 and 30-4. The macro node 10 and the RRHs 30-1 to 30-4 are connected with each other, for example by means of a wired connection like an optical fiber 25, or by any other suitable connection type, such as another wired or a wireless connection. Within the cell 40 controlled by the macro node 10 (indicated by the hexagonal box), the RRHs 30-1 to 30-4 form respective sub cells (indicated by dashed circles). Furthermore, a UE 20 is located in the coverage area of the macro cell 40, wherein the UE 20 is able to communicate with the network. The UE 20 may be located such that it is able to communicate also with one or more of the RRHs 30-1 to 30-4.

According to examples of embodiments of the invention, the macro node 10 comprises an array of antennas while the low power RRHs 30-1 to 30-4 may have one or an array of transmit antennas. It is to be noted that according to further examples of embodiments, there may be also the case that the macro node 10 itself does not comprise transmit antennas but represents only the communication network control function, i.e. it is just an entity performing e.g. radio resource management (RRM). In such a case the cell is populated, as transmission points, only with e.g. the low power RRHs 30-1 to 30-4 as shown in FIG. 1. Each antenna or array of antennas is to be understood as a transmission point (also referred to as transmit point). That means, the macro-node 10 is a transmission point (if provided with antennas) and the RRHs 30-1 to 30-4 are also transmission points. Since the RRH 30-1 to 30-4 and the macro-node 10 are connected, for example, through optical fibers 25 or another suitable connection type, feedback delays and capacity over the connection are considered as ideal and unlimited in the following.

In a scenario with a macro node and one or more RRHs as shown in FIG. 1, the macro node and the RRH may also differ in the utilized transmit powers.

The macro-node may operate in a range of, for example, 46/49 dBm in a 10/20 MHz carrier while the RRHs may operate, for example, with 30/37 dBm.

Basically, it is possible that each transmit point may have its own physical cell identifier (cell ID). That is, the sub cells covered by each RRH 30-1 to 30-4 is assigned to a respective different cell ID. Alternatively, all transmit points may have the same cell ID (i.e. all sub cells covered by each RRH 30-1 to 30-4 have the same cell ID as the macro cell). In other words, all the network nodes (macro, RRHs) under the communication network control element for area 40 (e.g. eNB 10) have the same cell ID. Anyhow, according to examples of embodiments of the invention, preferably only one central unit, which is also referred to hereinafter as scheduler element, is configured to perform scheduling of the radio resources. This scheduler element is usually comprised at the macro-node 10, i.e. the eNB, for example. According to other examples of embodiments, the scheduler element may be a separate entity/element different to the eNB 10 in charge of scheduling network nodes within area 40, wherein however a sufficient signaling capability for exchanging messages and parameters between the separate scheduler entity/element and the network is provided.

The RRHs 30-1 to 30-4 may be considered as antennas or arrays of antennas which are used in order to improve the spectral efficiency of the cell. Hence they can be also seen as simple RF front ends pulled away from the macro-node 10 but having no RRM capability.

From the network perspective, a scenario where the macro-node and RRHs have the same cell ID and a scenario where the macro-node and RRHs have respective different cell IDs represent the same deployment with different implementation. In the following, examples of embodiments of the invention are described which are related to a scenario where the macro-node and RRHs, i.e. all transmission points have the same cell ID. However, it is to be noted that other examples of embodiments of the invention are not limited to such a single cell ID case but may also be used in case with different cell IDs.

As indicated above, each transmission point as shown in FIG. 1, i.e. the macro node or eNB 10 and the RRHs 30-1- to 30-4 may be equipped with various number of transmit antennas. For example, it is considered that the macro node may have 2, 4 and 8 Tx antennas while an RRH may have 1, 2 or 4 Tx antennas. The antennas may be of co-polarized and cross-polarized types, wherein the same type of antennas may preferably be used for all transmission points in one given configuration. However, it is to be noted that the actual number of transmit antennas is not restricted to the above mentioned numbers, and there may be also 8 or even more Tx antennas also for RRHs. In addition, according to examples of embodiments of the invention, each transmission point may consist of one or a plurality of closely spaced antenna groups or CSAG. For example, a transmission point with widely space cross-polarized antennas may consist of two separate CSAGs (XX) (this configuration is also referred to as [XX XX], where each X represents a cross polarized antenna forming two closely arranged pairs XX with half lambda distance between the antennas forming each pair and larger distance between the two pairs).

As indicated in FIG. 1, the UE 20 is located in the cell 40 formed by the macro-node 10 and is also under the coverage of one or more RRHs (e.g. RRH30-3 and 30-1). Conventionally, in a non HetNet scenario with only a macro node, the UE 20 would know the number of transmit antennas existing at the transmit point to which it is connected (macro node or RRH/pico node) and report the channel state information (CSI) based on the common reference symbol (CRS) or channel state information reference symbol (CSI-RS) ports, depending on the respective network configuration and transmission mode.

On the other hand, in a HetNet scenario as depicted in FIG. 1, is may be assumed that according to examples of embodiments of the invention CSI-RS providing support for 1, 2, 4, and 8 Tx antennas, for example, operation for channel state report is also based on CSI-RS. That is, CSI-RS parameters, like periodicity and antenna pattern, are signaled as UE-specific information. In this HetNet scenario the UE 20 may hear the RRH (or several RRHs, like RRH 30-3 and 30-1, as indicated above) and the macro node, i.e. the eNB 10. In such case the UE 20 is signaled the specific antenna ports associated to the CSAG on which it has to perform CSI estimation. For example, if the UE 20 hears two RRHs 30-4 and 30-1 (each assumed to have one CSAG) and the macro node 10, it gets signaled the CSI-RS patterns of these three transmission points for which to compute CSI. Once channel estimation is performed, CSI feedback needs to be computed and reported to the macro node 10. As described below, according to examples of the present invention, both SU and MU MIMO is supported, so that the computed feedback for these three CSAGs enables closed-loop MIMO operation.

Another alternative is that the UE is aware of all available CSI-RS ports in the cell, from all the RRHs and macro node. The UE may compute and report CSI feedback for a subset of the total number of CSI-RS ports, based for example on the hearibility of the CSI-RS ports, that is CSI feedback for ports having the received power below a certain threshold might not be reported.

Generally, as feedback has to be computed for the CSAGs configured to the UE 20, each CSAG may, as indicated above, comprise different sized antenna arrays. Therefore, theoretically, there are several possibilities for computing feedback.

For example, it could be considered to utilize an “explicit channel feedback”, for example by using covariance matrix information of the CSAG channels or of the composite channel, i.e. the aggregated channel for all the CSAGs, and to feed it back to the central scheduling entity (i.e. typically the macro node or eNB 10).

Alternatively, it may be considered to use an “implicit feedback”, wherein codebooks can be utilized. Several solutions are possible here as well:
1. One can use the codebooks if they match with the number of antenna ports at each CSAG and UE may provide CSI feedback on a per CSAG basis. The latter feedback is then complemented with phase and/or amplitude combiners in order to obtain the joint precoder corresponding to all the CSAGs and hence enable coherent transmission from the virtual antenna array formed by the arrays of the CSAGs. For example, in case the CSAG has 2 or 4 Tx antennas, one can utilize 2 and 4 Tx codebooks. Similarly, for a 8 Tx antenna configuration, a double codebook approach may be used. In case 1 Tx antenna is used in a CSAG, one phase and/or amplitude combiner is needed to construct the joint precoder from all transmission points.
2. Another possibility is to operate on the composite channel from all the antenna ports of the CSAGs to the UE 20. It may be tried to utilize existing codebooks if the total number of antennas available from the CSAGs matches the size of a codebook. For example, if feedback is performed for three CSAGs, a 4 Tx precoder can be formed from 2 Tx antennas at the macronode plus two times 1 Tx antenna at the RRHs. Similarly, the 8 Tx codebook may be utilized when the total number of antenna ports from all the CSAGs is equal to eight. However in a HetNet scenario, this option may be not satisfying because the CSAGs may be geographically separated, i.e. the groups of arrays are geographically separated, so that the composite channel does not exhibit the same statistical/spatial properties for which the original codebooks have been designed and optimized for.
3. Still another possibility is to design new codebooks for the total number of antenna ports found in the composite channel between the CSAGs and the UE. However, in such a case, it is required to implement restrictions in terms of possible combinations of CSAGs in order to limit the number of possible codebooks to be designed and standardized.

In the following, examples of embodiments of the invention are described which explain the feedback framework for providing, for example, a CSI feedback operating in a macro-node and low power RRH scenario as depicted in FIG. 1 supporting both SU and MU MIMO, wherein the feedback framework provides enough flexibility so that various combinations of number of CSAGs, each consisting of various numbers of transmit antennas, are possible.

According to examples of embodiments of the invention, a feedback framework applicable to the HetNet MIMO scenario is provided which is able to cope with variable number of transmission points, wherein each transmission point may comprise one or more CSAGs, wherein each CSAG may consist one or more transmit antennas. For this purpose, a modular approach is provided in the feedback framework according to examples of embodiments of the invention in order to form of for example a double codebook construction.

For example, according to examples of embodiments of the invention, a feedback framework is provided in which codebooks for the CSAGs rather than for transmission points are provided. Thus, for example, there is provided also flexibility with regard to the placement of the respective CSAGs.

Basically, according to examples of embodiments of the invention, the concept of CSAG is assumed to comprise either one closely-spaced uniform linear array with N_{ULA}^{k} elements (N_{ULA}^{k}, are integers equal to or greater than 1), or a cross-polarized closely spaced antenna array with 2N_{ULA}^{k} elements. The upper-script k indexes the CSAG, i.e. k takes values k=1, . . . , K where K is the total number of CSAGs configured for CSI feedback. It is specifically assumed that any distributed antenna array may be built of such CSAG building blocks.

A precoding matrix W used from all CSAGs is formed as product of two matrices W₁ and W₂:

W=W₁W₂ (1)

The matrix W₁, which is also referred to as wideband long-term precoder, has a block diagonal structure, each block being mapped to the array size of a corresponding closely spaced antenna group. According to examples of embodiments of the invention, the matrix W₁ may have the following form:

$${W}_{1} = [ \begin{matrix}{W}_{1}^{1} & 0 & 0 & 0 \\ 0 & {W}_{1}^{2} & 0 & 0 \\ 0 & 0 & ⋱ & 0 \\ 0 & 0 & 0 & {W}_{1}^{K}\end{matrix} ] \qquad ( 2 )$$

where W₁¹, W₁², . . . W₁^{k}, . . . W₁^{K} are targeting wideband and/or long term channel properties for K closely spaced antenna groups (the upper-script k refers to the CSAG index k=1, . . . , K, while the sub-script indicates reference to the first precoder targeting for wideband and/or long term channel properties).

It is to be noted that the respective matrices W₁¹ etc. may contain for example DFT-based sub-matrices.

The matrices W₁¹, W₁² . . . and W₁^{K} may be selected from codebooks C₁¹, C₁² . . . and C₁^{K}, respectively, which are known to both the scheduler element (the eNB 10) and the respective UE 20, for example.

The matrices W₁^{K} themselves may have also a block diagonal structure:

$${W}_{1}^{K} = [ \begin{matrix}{X}_{1}^{K} & 0 \\ 0 & {X}_{1}^{K}\end{matrix} ] \qquad ( 3 )$$

where X₁^{K} may contain one or more beams for a sub-array (e.g. 2 Tx ULA part of a 4 Tx XP array), e.g. in the form of DFT-based sub-matrices. It is to be noted that the matrix X₁^{K} may also be an identity matrix or just a scalar equal to 1. Furthermore, each matrix W₁^{K} may also be just a scalar equal to the relative amplitude to account for any transmission points having for example one Tx antenna or another number of antennas or arrays. On the other hand, the matrix W₂, which is also referred to as sub-band short-term precoder, may contain both intra-transmission point combiners and inter-transmission point combiners.

The intra-transmission point combiners may consist of column selection vectors and co-phasing terms so that resulting beams are formed as a multiplication of W^{k}₁ and W^{k}₂ (to be described later). The goal of using intra-transmission point combiners is to form beams towards the UE from each transmission point or CSAG, respectively.

On the other hand, the inter-transmission point combiners are used to coherently combine the precoders in order to obtain the resulting precoder W. In other words, inter-transmission point combiners target coherent combining between the beams from each transmission point formed by the above described intra-transmission points combiners. Also the inter-transmission point combiners may comprise an amplitude term, which improves performance in cases where the transmissions from different transmission points are received with substantial power imbalance.

The matrix W₂, which targets the frequency-selective and/or short term channel properties, may have the following form:

$${W}_{2} = [ \begin{matrix}{W}_{2}^{1} \\ {W}_{2}^{2} \\ ⋮ \\ {W}_{2}^{K}\end{matrix} ] \qquad ( 4 )$$

The design of codebooks for the above mentioned W^{k}₁. and W^{k}2 precoders may be done for both cross- and co-polarized antenna configurations.

It is to be further noted that while the above described codebook structure according to examples of embodiments of the invention is designed mainly for HetNets where multiple transmission points are participating in the transmission, it is also applicable for a single transmission point transmission scenario (for example a single-cell transmission). In this case, by means of the same operation, it is possible to obtain also for a single transmit point transmission a codebook structure corresponding to single transmission point double codebook (i.e. there is no need to use another processing, for example one corresponding to an LTE release 10 8Tx codebook). Specifically, examples of embodiments of the invention are also applicable to scenarios with a single transmission point having widely spaced antennas; in this case the codebook may consist e.g. of two closely-spaced antenna groups and the related intra-transmission point combiners.

In the following, further examples of embodiments of the invention are described in which the above described feedback framework is implemented in a scenario based on the structure shown in FIG. 1. In the following examples of embodiments of the invention, it is assumed that in a network structure as shown in FIG. 1, a total of three transmission points (e.g. macro node 10 and RRHs 30-1 and 30-4), each comprising one CSAG equipped with crossed-polarized antenna arrays in the following configuration is communicating with the UE 20:
the first transmit point (e.g. the eNB 10) comprises 4 Tx cross-polarized antenna arrays (ULA sub-array consists of two antenna elements, i.e. N_{ULA}¹=2);
the second and third transmit points (e.g. RRH 30-1 and RRH 30-3) comprise each 2 Tx cross-polarized antennas (ULA sub-array consists of one antenna element, i.e. N_{ULA}²=1 and N_{ULA}³=1).

These three CSAGs are forming a virtual array of 8 Tx antennas. However, it is to be noted that the feedback framework as described above may be used with any possible configuration of antennas (including odd dimensions of a virtual array).

In accordance with the above described feedback framework, for forming the final precoder W, a wide-band long-term precoder W₁ is to be computed for the above scenario.

Assuming a total number of K closely spaced antenna groups (K is an integer equal to or greater than 1), the base block of the codebook framework is an uniform linear array (ULA) element codebook

$$C ( {X}_{{N}_{ULA}^{k} \times {N}_{b}} )$$

size N_{ULA}^{k} times N_{b}, employing beam(s)/vector(s) per codeword (or beam group) taken from a grid of beams matrix

$${G}_{{N}_{ULA}^{k} \times M}$$

containing all the possible beams over the ULA part of the antenna array in the codebook. In the present examples of embodiments of the invention, the number of antennas in the ULA sub-array at the k-th closely spaced antenna group is N_{ULA}^{k}={1,2,4,8}, and the total number of available beams is denoted by M. Assuming an example of codebook C(X_{2×N}_{_{b}}) for two antennas at the k-th closely spaced antenna group N_{ULA}^{k}=2 in the ULA sub-array and M=4 beams in the grid of beams

$${G}_{{N}_{ULA}^{k} \times M} ,$$

then the following is obtained:
For N_{b}=1 (1 beam per codeword):

$${X}_{2 \times 1} = \{ [ \begin{matrix}1 \\ 1\end{matrix} ] , [ \begin{matrix}1 \\ j\end{matrix} ] , [ \begin{matrix}1 \\ - 1\end{matrix} ] , [ \begin{matrix}1 \\ - j\end{matrix} ] \} ,$$

meaning a selection of all beams from G_{2×4}
For N_{b}=2 (2 beams per codeword):

$${X}_{2 \times 2} = \{ [ \begin{matrix}1 & 1 \\ 1 & - 1\end{matrix} ] ; [ \begin{matrix}1 & 1 \\ 1 & j\end{matrix} ] ; [ \begin{matrix}1 & 1 \\ 1 & - j\end{matrix} ] ; [ \begin{matrix}1 & 1 \\ - 1 & j\end{matrix} ] ; [ \begin{matrix}1 & 1 \\ - 1 & - j\end{matrix} ] ; [ \begin{matrix}1 & 1 \\ j & - j\end{matrix} ] \} ,$$

meaning a selection of all possible combinations of two beams out of M=4 beams in G_{2×4}.

With the above described configuration of three CSAGs, the wideband/long-term precoder W₁ for the three closely spaced antenna groups may be written as:

$$\begin{matrix}{W}_{1}^{XP} = [ \begin{matrix}{W}_{1}^{1} & 0 & 0 \\ 0 & {W}_{1}^{2} & 0 \\ 0 & 0 & {W}_{1}^{3}\end{matrix} ] \\ = [ \begin{matrix}{α}_{1} {X}_{2 \times {N}_{b}}^{1} & 0 & 0 & 0 & 0 & 0 \\ 0 & {α}_{1} {X}_{2 \times {N}_{b}}^{1} & 0 & 0 & 0 & 0 \\ 0 & 0 & {α}_{2} & 0 & 0 & 0 \\ 0 & 0 & 0 & {α}_{2} & 0 & 0 \\ 0 & 0 & 0 & 0 & {α}_{3} & 0 \\ 0 & 0 & 0 & 0 & 0 & {α}_{3}\end{matrix} ] ,\end{matrix}$$

where the base codewords

$${X}_{{N}_{ULA}^{k} \times {N}_{b}}$$

describing long-term/wideband channel properties at each closely spaced antenna group are defined as:

$${W}_{1}^{1} = [ \begin{matrix}{α}_{1} {X}_{2 \times {N}_{b}}^{1} & 0 \\ 0 & {α}_{1} {X}_{2 \times {N}_{b}}^{1}\end{matrix} ] , {W}_{1}^{2} = {α}_{2} [ \begin{matrix}1 & 0 \\ 0 & 1\end{matrix} ] and$$

$${W}_{1}^{3} = {α}_{3} [ \begin{matrix}1 & 0 \\ 0 & 1\end{matrix} ] ,$$

where αᵢ is an average cell gain proportional to the pathloss experienced by the UE 20 towards the i-th CSAG (a is also referred to as relative pathloss vector). It is to be noted that for 2 Tx cross-polarized antennas at RRHs in second and third CSAG the ULA sub-array consists of a single antenna element. Since N_{ULA}²=1 and N_{ULA}³=1, from 3^{rd} block diagonal element onwards, X_{1×1}=1.

Further, for uniform linear arrays, the codeword for W₁ may be simplified as

$${W}_{1}^{ULA} = [ \begin{matrix}{α}_{1} {X}_{4 \times {N}_{b}}^{1} & 0 & 0 \\ 0 & {α}_{1} {X}_{2 \times {N}_{b}}^{2} & 0 \\ 0 & 0 & {α}_{1} {X}_{2 \times {N}_{b}}^{3}\end{matrix} ] .$$

It is to be noted that the codebook for a in this example may be a vector having a dimension of e.g. 3×1 normalized to 1, for example.

Furthermore, in accordance with the above described feedback framework, for forming the final precoder W, a sub-band short-term precoder W₂ is to be computed for the above scenario.

According to examples of embodiments of the invention, the structure of the sub-band short-term precoder W₂ can be constructed in two ways. The first way is to compute, independently per transmission point, beam selectors and co-phasing terms and inter-transmission point combiners. The second way is to use a joint codebook.

With regard to the first way, i.e. to determine independent per transmit point beam selectors and co-phasing terms and inter-transmit point combiners, the sub-band short-term precoder W₂ may have the following form for the above mentioned example using three CSAGs.

$${W}_{2} = [ \begin{matrix}{W}_{S \times R}^{2 , 1} \\ {W}_{S \times R}^{2 , 2} {c}_{2} \\ {W}_{S \times R}^{2 , 3} {c}_{3}\end{matrix} ] ,$$

where W_{S×R}^{2,k} has a dimension of S times R, with S=2N_{b} for cross-polarized antenna arrays (where there is one dimension per polarization), or S=N_{b} for uniform linear arrays, wherein R={1,2} is a rank of the transmission and cₖ is an inter-cell combiner element.

In the above example, the precoder W^{2,k} structure is shown up to a rank R=2. However, it is to be noted that the proposed concept is applicable also to higher ranks.

An example of codebook C(W^{2,k}) is indicated below:
For N_{b}=1, R=1, the per transmission point beam selectors/co-phasing terms are taken from a codebook like the following:

$$C ( {W}^{2 , k} ) = [ [ \begin{matrix}1 \\ 1\end{matrix} ] , [ \begin{matrix}1 \\ - 1\end{matrix} ] , [ \begin{matrix}1 \\ - j\end{matrix} ] , [ \begin{matrix}1 \\ j\end{matrix} ] ]$$

The inter-transmit point combiners may be taken from a codebook C(cₖ)=[1,−1].
This requires 3 (i.e. number of transmit points W^{2,k})×2-bit_CB+2 (number of combiners)×1 bit=8 bits
Hence for a rank of 1, the total W₂ feedback for three transmission points, consisting of codebooks and combiners, equals to 8 bits.
For N_{b}=1, R=2, the per transmission point beam selectors/co-phasing terms are taken from a codebook

$$C ( {W}^{2 , k} ) = [ [ \begin{matrix}1 & 1 \\ 1 & - 1\end{matrix} ] , [ \begin{matrix}1 & 1 \\ j & - j\end{matrix} ] ] .$$

The inter-transmission point combiners may be taken from a codebook

$$C ( {c}_{2} ) = [ [ \begin{matrix}1 & 0 \\ 0 & 1\end{matrix} ] , [ \begin{matrix}1 & 0 \\ 0 & - 1\end{matrix} ] ] .$$

This requires 3 (number of transmission points W^{2,k})×1-bit_CB+2 (number of combiners)×1bit=5 bits.
Hence, for a rank of 2, the total W^{2,k} feedback for three transmission points, consisting of codebooks and combiners, equals 5 bits.

It is to be noted that the amount of bits may be further decreased, e.g. by using a IID joint (combiners+per cell W^{2,k} feedbacks) codebook C(W^{2,k}) design. However, in order to keep R=2 codebook orthogonal, the matrix W^{2,k} has to be kept block orthogonal.

With regard to the second way, i.e. to use a joint codebook, according to examples of embodiments of the invention, joint codebooks C(W^{2,k}) for a set of K CSAGs are expected to be of different dimensions, depending on the antenna configurations at each of the transmission points. For example, the following dimensions may be provided:
1. cross-polarized 4 Tx for macro node, 2 Tx for RRH 1, 2 Tx for RRH 2: codebook dimension 6×R
2. cross-polarized 4 Tx for macro node, 1 Tx for RRH 1, 1 Tx for RRH 2: codebook dimension 4×R
3. single-polarized 8 Tx for macro node, 4 Tx for RRH 1, 4 Tx for RRH 2: codebook dimension 3×R

Since there are multiple dimensions for a given number K of CSAGs, it is necessary to provide multiple codebooks. However, by restricting the possible antenna configurations, it is possible to decrease the number of required joint codebooks. According to examples of embodiments, the codebook may be designed with constant modulus property, because pathloss for each CSAGs is fed back separately.

Another possible antenna configuration for one transmission point is an array of widely spaced cross-polarized sub-arrays [XX XX]. According to further examples of embodiments of the invention, such a configuration may be signaled to the UE 20 as two separate cross-polarized [XX] CSAGs, which requires only one additional long-term wide-band a feedback, compared to a case when an array [XX XX] is signaled to the UE 20 as only one closely spaced antenna array.

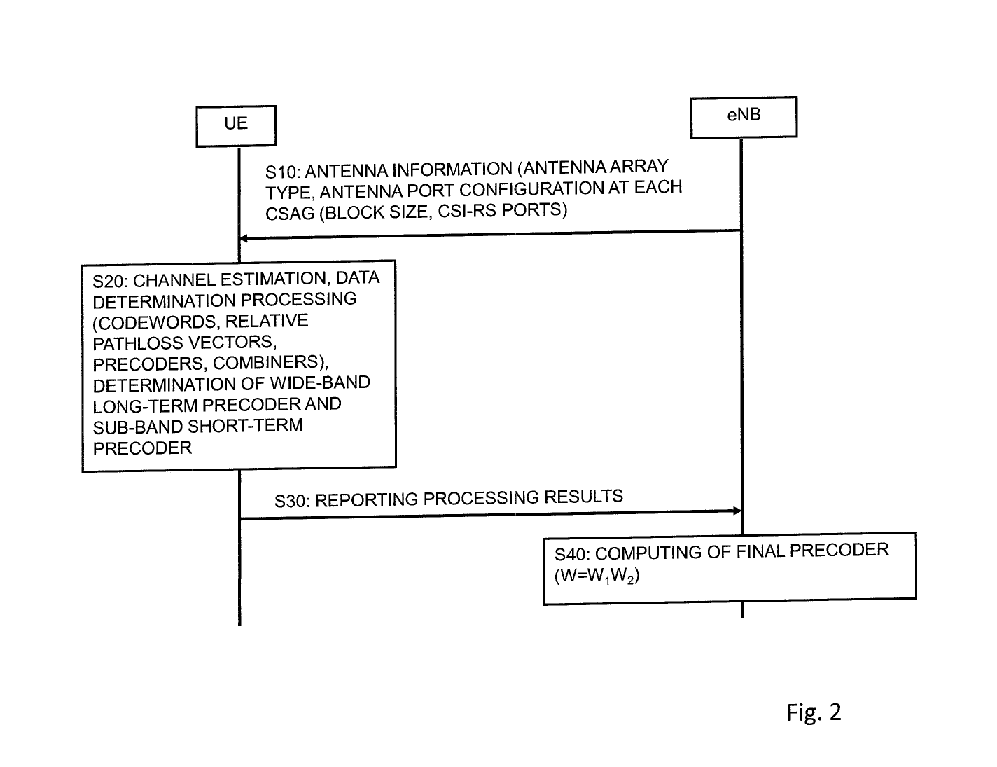

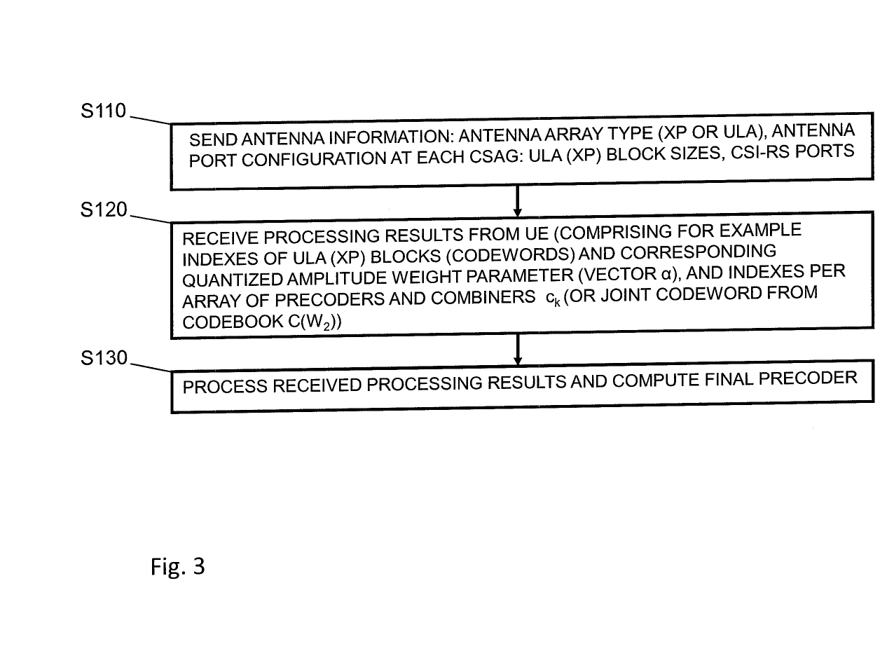

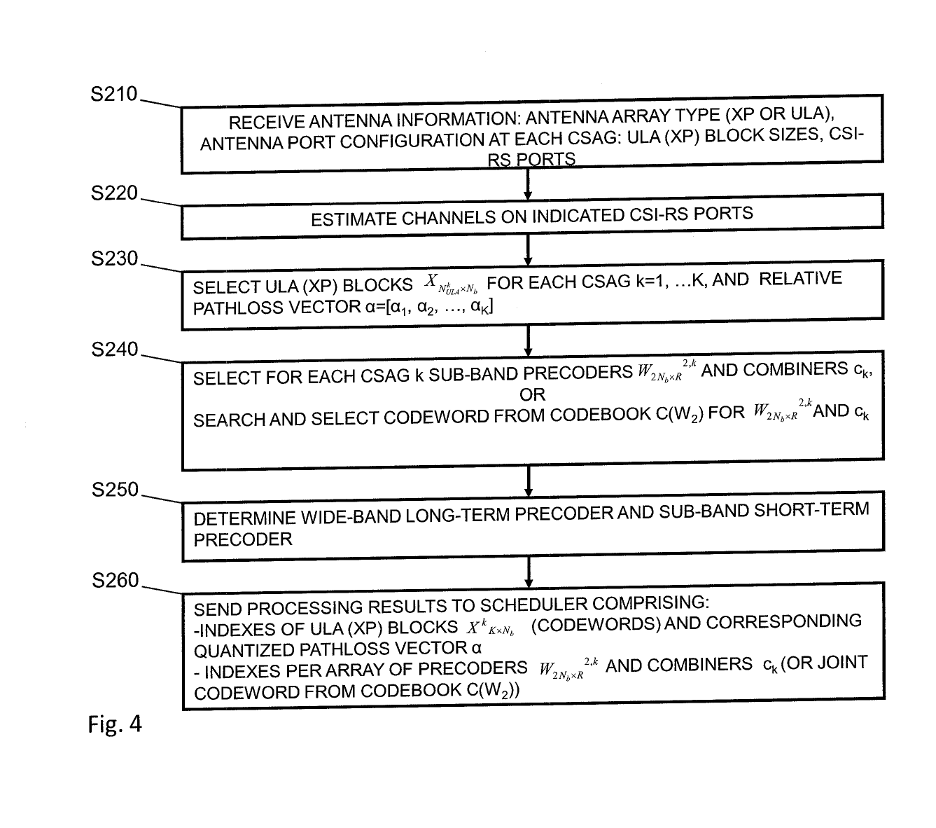

In the following, with regard to the signaling diagram according to FIG. 2 and the flow charts according to FIGS. 3 and 4, the processings executed by the eNB 10 (as the scheduler node) and the UE 20 operating according to the above described CSI feedback framework is described.

As shown in FIG. 2, in a step S10, the eNB 10 sends to the UE 20 antenna information. It is to be noted that the antenna information may be sent also from another network element than the eNB 10, e.g. from a network element acting as a transmitter for a scheduler element, or the like. The antenna information may comprise, for example, information regarding grouping of the antennas in each CSAG, i.e. indicating a CSAG grouping, an antenna array type and antenna port configuration data of each CSAG of the transmission points (i.e. block sizes and assigned CSI-RS ports). In other words, information are sent from the eNB 10 to the UE 20, not only a list regarding all antenna ports required to be measured, but also a grouping indication informing about the grouping of the antenna ports so that the UE is able to form a codebook for e.g. W₁ precoder in an intended way (as discussed above). According to a further example of embodiments of the invention, the antenna information may comprise not (only) such information so as to indicate the antenna array type in each CSAG in an explicit manner. Instead (or additionally), in order to support both XP and ULA configurations, codebooks used to select subband precoders include codewords (intra transmission point combiners) for both types of antenna arrays (ULA and XP). That is, a procedure being similar to an 8-Tx double codebook as described for example in LTE Rel-10 may be also employed.

After having received the antenna information, the UE 20 starts processing in step S20 by conducting a channel estimation based on the received antenna port configuration data, i.e. in the indicated CSI-RS ports, and a CSI determination for determining the precoders and channel quality indication, based on the known codebooks. That is, for example, the UE 20 conducts a selection/computation of at least one of precoding codewords for each CSAG and an amplitude weight parameter for each CSAG. The amplitude weight parameter may be, for example, a pathloss related parameter (relative pathloss vector a). The precoding codewords and the amplitude weight parameter may be used for determining the precoder indicated above. Furthermore, the UE 20 conducts a determination processing for determining information related to the precoder W₂, i.e. to information related to at least one of a sub-band precoder and a transmission point related combiner, that is by determining independent per transmission point beam selectors and co-phasing terms and inter-transmit point combiners, or by searching a joint codebook for a corresponding suitable codeword. It is to be noted that in case of, for example, a one Tx antenna single transmission point, there is no need to determine a sub-band precoder, but it is sufficient to determine (and report) a transmit point related combiner, for example. Then, the UE 20 is able to compute or determine the wide-band long-term precoder W₁, as described above, and the precoder W₂ (based on sub-band precoder and transmission point related combiner), as described above.

In step S30, the UE 20 reports the processing results of step S20 to a network element, e.g. the scheduler element, i.e. the eNB 10, for example.

In step S40, after having received the processing results from the UE 20, the eNB 10 determines the final precoder W on the basis of the received processing results. In other words, the eNB 10 determines the final precoder on the basis of received CSI feedbacks. As one (not limiting) implementation example, the codewords for the CSAGs and the amplitude weight parameter (e.g. related to the pathloss experienced by the UE 20 towards each CSAG) are used to determine the wide-band long-term precoder W₁, as described above, and the information related to the precoder W₂ (sub-band precoder and transmission point related combiner) is used to determine the sub-band short-term precoder W₂, as described above, wherein the final precoder W may be computed by W=W₁W₂.

In the flow chart according to FIG. 3, the processing conducted by the scheduler element or eNB 10 is explained in further detail.

In step S110, which is related to step S10 according to FIG. 2, the signaling of the antenna information to the UE is initiated, for example the eNB signals to the UE the antenna information. As indicated above, the antenna information informs about the CSAG grouping and comprise e.g. one bit indicating the type of antenna array (XP or ULA), and information on the antenna port configuration at each CSAG: ULA (XP) block sizes and assigned CSI-RS ports.

In step S120, the scheduler element (eNB 10) receives and processes, in accordance with steps S30 and S40, the processing results of the UE 20 (described below in further detail). That is, the eNB 10 receives e.g. an index related to the wide-band long-term precoder and an index related to the sub-band short-term precoder, for example in the form of indexes of ULA (XP) blocks X^{k}_{K×N}_{_{b}} and corresponding quantized vector α(for W1 determination), and indexes per array of

$${W}_{2 {N}_{b} \times R}^{2 , k}$$

precoders and combiners cₖ (or a joint codeword from codebook C(W₂)).

Then, in step S130, which is also related to step S40 of FIG. 2, the scheduler element (eNB 10) computes the final precoder W based on the information (processing results) received in step 120.

In the flow chart according to FIG. 4, the processing conducted by the UE 20 is explained in further detail.

In step S210, which is related to step S10 according to FIG. 2, the UE receives from the eNB 10 the antenna information. As indicated above, the antenna information informs about the CSAG grouping and comprise e.g. one bit indicating the type of antenna array (XP or ULA), and information on the antenna port configuration at each CSAG: ULA (XP) block sizes and assigned CSI-RS ports.

In step S220, the UE 20 estimates the channels on the indicated CSI-RS ports.

Then, in step S230, the UE 20 selects ULA (XP) blocks

$${X}_{{N}_{ULA}^{k} \times {N}_{b}} ,$$

for each closely spaced antenna group k=1, . . . K, and the relative pathloss vector α=[α₁, α₂, . . . , α_{K}]. Furthermore, in step S240, the UE 20 selects for each closely spaced antenna group k sub-band precoders

$${W}_{2 {N}_{b} \times R}^{2 , k}$$

and combiners cₖ; alternatively, the UE 20 searches jointly for

$${W}_{2 {N}_{b} \times R}^{2 , k}$$

and cₖ by selecting a codeword from the codebook C(W₂). In step S250, wide-band long-term precoder W₁ and sub-band short-term precoder W₂ may be determined on the basis of the processing results.

Steps S210 to S250 are related to step S20 of FIG. 2.

In step S260, which is related to step S30 of FIG. 2, the UE 20 reports to the scheduler element an index related to the wide-band long-term precoder and an index related to the sub-band short-term precoder, for example in the form of indexes of ULA (XP) blocks X^{k}_{K×N}_{_{b}} and corresponding quantized vector α, and reports indexes of per array

$${W}_{2 {N}_{b} \times R}^{2 , k}$$

precoders and combiners cₖ (or joint codeword from codebook C(W₂)). It is to be noted that for an amplitude weight parameter indication (i.e. for α, for example) an index from a codebook related to the amplitude weight parameter may be sent.

By means of the above described feedback framework, it is possible that the serving cell assembles feedback components in order to match best the channel properties. For example, if the channel has a large angular spread, with closely spaced ULA antennas e.g 1^{st} and 5^{th} [2λ distance] antenna array elements are no longer correlated. Thus, the serving cell may configure 8 Tx array as two 4 Tx arrays by means of which it is possible to better fit the feedback to channel conditions.

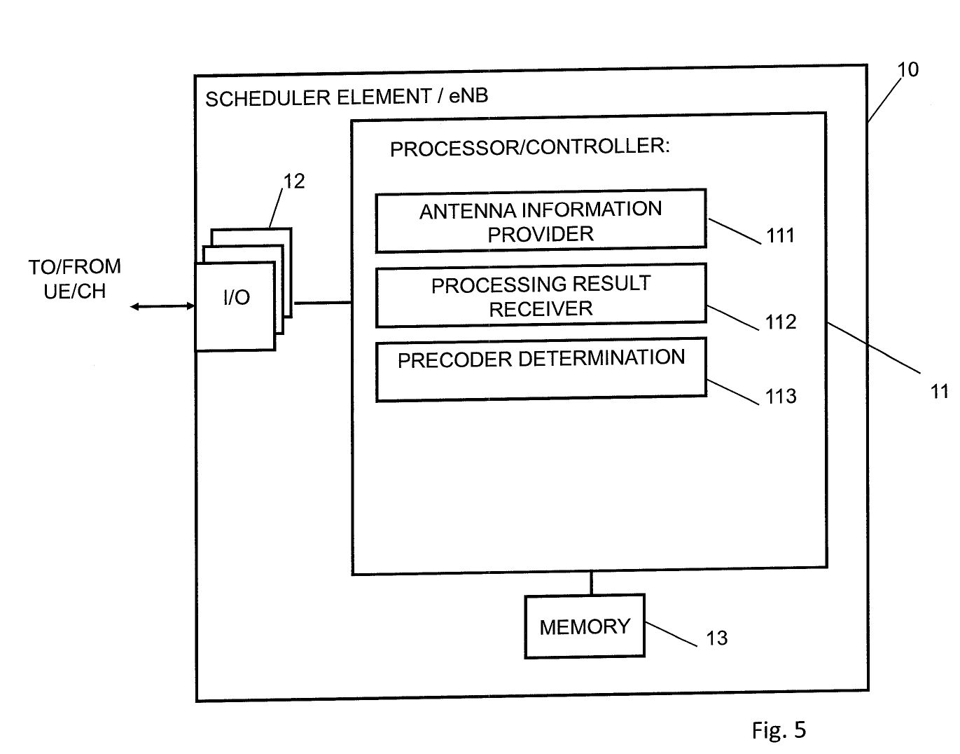

In FIG. 5, a block circuit diagram illustrating a configuration of a communication network control element, such as the eNB 10, is shown, which is configured to implement functions of the scheduler element and thus of the processing as described in connection with the examples of embodiments of the invention according to FIG. 3, for example. It is to be noted that the communication network control element or eNB 10 shown in FIG. 5 may comprise several further elements or functions besides those described herein below, which are omitted herein for the sake of simplicity as they are not essential for understanding the invention. Furthermore, even though reference is made to an eNB, the communication network element may be also another device having a similar function, such as a modem chipset, a chip, a module etc., which can also be part of a BS or attached as a separate element to a BS, or the like.

The communication network control element or eNB 10 may comprise a processing function or processor 11, such as a CPU or the like, which executes instructions given by programs or the like related to the power control. The processor 11 may comprise one or more processing portions dedicated to specific processing as described below, or the processing may be run in a single processor. Portions for executing such specific processing may be also provided as discrete elements or within one or more further processors or processing portions, such as in one physical processor like a CPU or in several physical entities, for example. Reference sign 12 denotes interface or transceiver or input/output (I/O) units connected to the processor 11. The I/O units 12 may be used for communicating with elements of the cellular network, such as a communication network element like a UE. The I/O units 12 may be a combined unit comprising communication equipment towards several network elements, or may comprise a distributed structure with a plurality of different interfaces for different network elements. Reference sign 13 denotes a memory usable, for example, for storing data and programs to be executed by the processor 11 and/or as a working storage of the processor 11.

The processor 11 is configured to execute processing related to the above described feedback framework. In particular, the processor 11 comprises a sub-portion 111 as a processing portion which is usable as an antenna information provider which provides the antenna information towards the UE. The portion 111 may be configured to perform processing according to step S110 according to FIG. 3, for example. Furthermore, the processor 11 comprises a sub-portion 112 as a processing portion which is usable as a processing result receiving portion which is able to receive the processing results from the UE for determining the final precoder W. The portion 112 may be configured, for example, to perform processing according to step S120 according to FIG. 3, for example. Moreover, the processor 11 comprises a sub-portion 113 as a precoder determination processing portion which is usable to process the received processing results and to compute the final precoder W. The portion 113 may be configured, for example, to perform processing according to step S130 according to FIG. 3, for example.

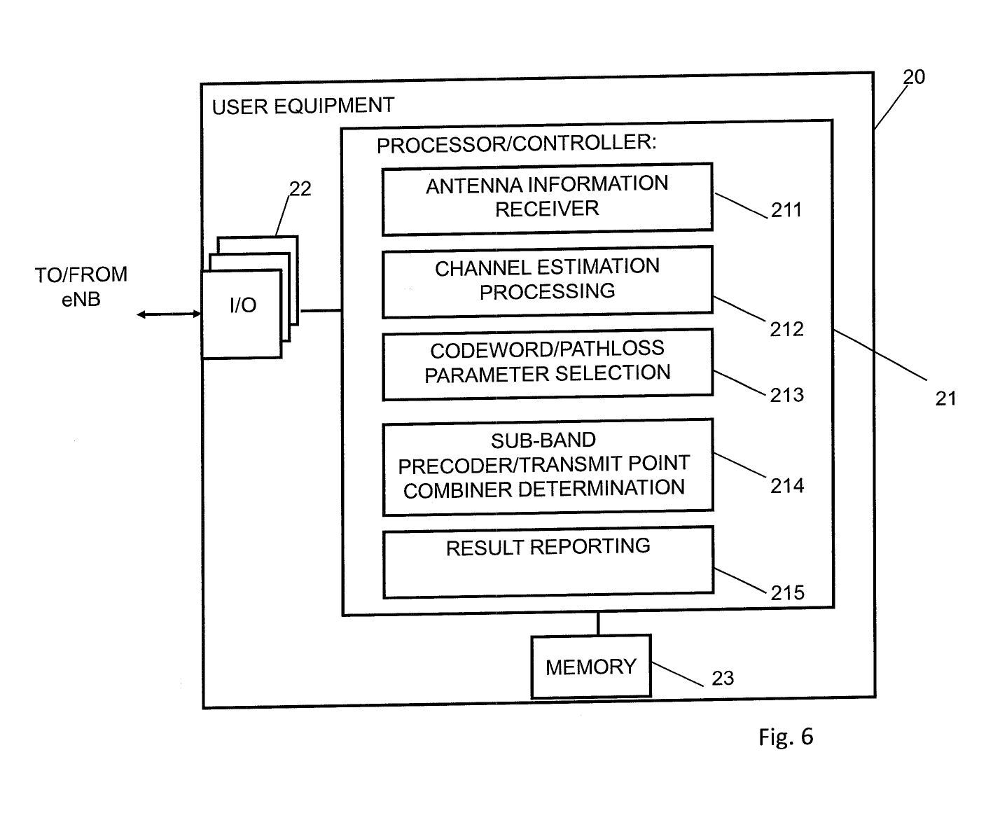

In FIG. 6, a block circuit diagram illustrating a configuration of a communication network element, such as of UE 20, is shown, which is configured to implement the processing as described in connection with the examples of embodiments of the invention according to FIG. 4, for example. It is to be noted that the communication network element or UE 20 shown in FIG. 6 may comprise several further elements or functions besides those described herein below, which are omitted herein for the sake of simplicity as they are not essential for understanding the invention. Furthermore, even though reference is made to a UE, the communication network element may be also another device having a similar function, such as a modem chipset, a chip, a module etc., which can also be part of a UE or attached as a separate element to a UE, or the like.

The communication network element or UE 20 may comprise a processing function or processor 21, such as a CPU or the like, which executes instructions given by programs or the like related to the power control. The processor 21 may comprise one or more processing portions dedicated to specific processing as described below, or the processing may be run in a single processor. Portions for executing such specific processing may be also provided as discrete elements or within one or more further processors or processing portions, such as in one physical processor like a CPU or in several physical entities, for example. Reference sign 22 denotes interfaces or transceivers or input/output (I/O) units connected to the processor 21.

The I/O units 22 may be used for communicating with elements of the communication network, such as a communication network control element like an eNB. The I/O units 22 may be a combined unit comprising communication equipment towards several of the network element in question, or may comprise a distributed structure with a plurality of different interfaces for each network element in question. Reference sign 23 denotes a memory usable, for example, for storing data and programs to be executed by the processor 21 and/or as a working storage of the processor 21.

The processor 21 is configured to execute processing related to the above described feedback framework. In particular, the processor 21 comprises a sub-portion 211 as a processing portion which is usable for receiving antenna information from the scheduler element. The portion 211 may be configured to perform processing according to step S210 according to FIG. 4, for example. Furthermore, the processor 21 comprises a sub-portion 212 as a processing portion for channel estimation. The portion 212 may be configured to perform processing according to step S220 according to FIG. 4, for example. Moreover, the processor 21 comprises a sub-portion 213 as a processing portion which is usable for selecting codewords and computing pathloss related parameters. The portion 213 may be configured to perform processing according to step S230 according to FIG. 4, for example. In addition, the processor 21 comprises a sub-portion 214 as a processing portion which is usable for determining sub-band precoder/transmit point combiner. The portion 214 may be configured to perform processing according to step S240 according to FIG. 4, for example. Furthermore, the processor 21 comprises a sub-portion 215 as a processing portion which is usable for reporting processing results to the scheduler element. The portion 215 may be configured to perform processing according to step S260 according to FIG. 4, for example.

As described above, according to examples of embodiments of the invention, there is proposed a feedback framework where matrices W1 and W2 are used to form a joint or final precoder from multiple transmission points. The precoder or matrix W1 incorporates an average cell gain proportional to the pathloss experienced with respect to a particular group of CSAGs. It is applicable to any array size. The matrix or precoder W2 can be constructed either with independent per transmission point beam selectors and co-phasing terms and inter-transmit point combiners or based on a joint codebook. The network signals to the UE the CSI-RS groups and the UE is configured to make use of the codebooks based on this signaling. By the thus proposed feedback it is possible to accommodate new deployment for widely (4-10λ) spaced X-polarized arrays [XX----XX].

As described above, examples of embodiments of the invention concerning the feedback framework are described to be implemented in UEs and eNBs. However, the invention is not limited to this. For example, examples of embodiments of the invention may be implemented in any wireless modems or the like.

According to a further example of an embodiment of the invention, there is provided, for example, an apparatus comprising receiving means for receiving antenna information from a scheduler element, the antenna information comprising information indicating a grouping of one or more antenna in at least one closely spaced antenna group of one or more transmit points, estimating processing means for estimating channels based on the received antenna information, selecting processing means for selecting at least one of a precoding codeword and an amplitude weight parameter for each of the at least one closely spaced antenna group, determining processing means for determining information related to at least one of a sub-band precoder and a transmit point related combiner, and reporting processing means for reporting processing results of the selecting processing means and the determining processing means to the scheduler element.

Moreover, according to another example of an embodiment of the invention, there is provided, for example, an apparatus comprising signaling processing means initiating transmission of antenna information to a communication network element, the antenna information comprising information indicating a grouping of one or more antenna in at least one closely spaced antenna group of one or more transmit points, receiving processing means for receiving processing results from the communication network element, the processing results comprising at least one of an index of precoding codewords and an index of an amplitude weight parameter for each of the at least one closely spaced antenna group, and at least one of an index of a sub-band precoder and an index of a transmit point related combiner, and a processing means for processing the received processing results and for computing a final precoder on the basis the received processing results.

For the purpose of the present invention as described herein above, it should be noted that
an access technology via which signaling is transferred to and from a network element may be any technology by means of which a network element or sensor node can access another network element or node (e.g. via a base station or generally an access node). Any present or future technology, such as WLAN (Wireless Local Access Network), WiMAX (Worldwide Interoperability for Microwave Access), LTE, LTE-A, Bluetooth, Infrared, and the like may be used; although the above technologies are mostly wireless access technologies, e.g. in different radio spectra, access technology in the sense of the present invention implies also wired technologies, e.g. IP based access technologies like cable networks or fixed lines but also circuit switched access technologies; access technologies may be distinguishable in at least two categories or access domains such as packet switched and circuit switched, but the existence of more than two access domains does not impede the invention being applied thereto,
usable communication networks and transmission nodes may be or comprise any device, apparatus, unit or means by which a station, entity or other user equipment may connect to and/or utilize services offered by the access network; such services include, among others, data and/or (audio-) visual communication, data download etc.;
a user equipment or communication network element may be any device, apparatus, unit or means by which a system user or subscriber may experience services from an access network, such as a mobile phone, personal digital assistant PDA, or computer, or a device having a corresponding functionality, such as a modem chipset, a chip, a module etc., which can also be part of a UE or attached as a separate element to a UE, or the like;
method steps likely to be implemented as software code portions and being run using a processor at a network element or terminal (as examples of devices, apparatuses and/or modules thereof, or as examples of entities including apparatuses and/or modules for it), are software code independent and can be specified using any known or future developed programming language as long as the functionality defined by the method steps is preserved;
generally, any method step is suitable to be implemented as software or by hardware without changing the idea of the invention in terms of the functionality implemented;
method steps and/or devices, apparatuses, units or means likely to be implemented as hardware components at a terminal or network element, or any module(s) thereof, are hardware independent and can be implemented using any known or future developed hardware technology or any hybrids of these, such as a microprocessor or CPU (Central Processing Unit), MOS (Metal Oxide Semiconductor), CMOS (Complementary MOS), BiMOS (Bipolar MOS), BiCMOS (Bipolar CMOS), ECL (Emitter Coupled Logic), TTL (Transistor-Transistor Logic), etc., using for example ASIC (Application Specific IC (Integrated Circuit)) components, FPGA (Field-programmable Gate Arrays) components, CPLD (Complex Programmable Logic Device) components or DSP (Digital Signal Processor) components; in addition, any method steps and/or devices, units or means likely to be implemented as software components may for example be based on any security architecture capable e.g. of authentication, authorization, keying and/or traffic protection;
devices, apparatuses, units or means can be implemented as individual devices, apparatuses, units or means, but this does not exclude that they are implemented in a distributed fashion throughout the system, as long as the functionality of the device, apparatus, unit or means is preserved; for example, for executing operations and functions according to examples of embodiments of the invention, one or more processors may be used or shared in the processing, or one or more processing sections or processing portions may be used and shared in the processing, wherein one physical processor or more than one physical processor may be used for implementing one or more processing portions dedicated to specific processing as described,
an apparatus may be represented by a semiconductor chip, a chipset, or a (hardware) module comprising such chip or chipset; this, however, does not exclude the possibility that a functionality of an apparatus or module, instead of being hardware implemented, be implemented as software in a (software) module such as a computer program or a computer program product comprising executable software code portions for execution/being run on a processor;
a device may be regarded as an apparatus or as an assembly of more than one apparatus, whether functionally in cooperation with each other or functionally independently of each other but in a same device housing, for example.

As described above, there is provided a mechanism providing a flexible feedback framework operating in different scenarios, such as heterogeneous network deployments. Antenna information are sent from a scheduler element to a UE, the antenna information comprising information indicating a grouping of one or more antenna in closely spaced antenna groups of one or more transmit points. The UE selects at least one of precoding codewords and amplitude weight parameters for each closely spaced antenna group, and determines information related to a sub-band precoder and a transmit point related combiner. The processing results are indicated to the scheduler by means of sending indices related to a wide-band long-term precoder and a sub-band short-term precoder. The scheduler processes these results for determining a joint precoder.

Although the present invention has been described herein before with reference to particular embodiments thereof, the present invention is not limited thereto and various modifications can be made thereto.

1. An apparatus comprising
a receiver configured to receive antenna information, the antenna information comprising information indicating a grouping of one or more antenna in at least one closely spaced antenna group of one or more transmit points,
an estimating processing portion configured to estimate channels based on the received antenna information,
a selecting processing portion configured to select at least one of a precoding codeword and an amplitude weight parameter for each of the at least one closely spaced antenna group,
a determining processing portion configured to determine information related to at least one of a sub-band precoder and a transmit point related combiner, and
a reporting processing portion configured to report processing results of the selecting processing portion and the determining processing portion.

2. The apparatus according to claim 1, wherein
the antenna information further comprises antenna port configuration data of the at least one closely spaced antenna group of the one or more transmit points, and wherein the information indicating the grouping in the at least one closely spaced antenna group includes, for each of the at least one closely spaced antenna group, antenna array block size indication and information on assigned channel state information reference signal ports.

3. The apparatus according to claim 1, wherein
the antenna information further comprises an identification of an antenna array type of each of the at least one closely spaced antenna group as being one of a uniform linear array type or a cross polarized array type.

4. The apparatus according to claim 1, wherein
the amplitude weight parameter comprises one of an average cell gain parameter proportional to a pathloss experienced towards each of the at least one closely spaced antenna group, or a relative pathloss vector.

5. The apparatus according to claim 1, wherein
the determining processing portion configured to determine information related to at least one of the sub-band precoder and the transmit point related combiner is further configured to perform one of
a computation of at least one of the sub-band precoder and the transmit point related combiner for each of the at least one closely spaced antenna group by determining independently per transmit point beam selectors and co-phasing terms and transmit point related combiners, and
a search in a joint codebook and a selection of a corresponding codeword in the joint codebook for identifying at least one of a suitable sub-band precoder and transmit point related combiner.

6. The apparatus according to claim 5, wherein the transmit point related combiner comprises at least one of an intra-transmission point combiner and an inter-transmission point combiner.

7. The apparatus according to claim 1, wherein the reporting processing portion configured to report the processing results of the computing processing portion and the determining processing portion is further configured to send an index related to a wide-band long-term precoder based on the selected at least one of the precoding codeword and the amplitude weight parameter or an index from a codebook related to the amplitude weight parameter, and an index related to a sub-band short-term precoder based on
one of
an index per closely spaced antenna group of at least one of computed sub-band precoders and transmit point related combiners, or
a selected codeword of a joint codebook for identifying at least one of a suitable sub-band precoder and transmit point related combiner.

8. The apparatus according to claim 7, wherein the wide-band long-term precoder is in the form of a first matrix W₁ having a block diagonal structure, wherein each block being mapped to the array size of a corresponding closely spaced antenna group, the first matrix W₁ having a form of
$${W}_{1} = [ \begin{matrix}{W}_{1}^{1} & 0 & 0 & 0 \\ 0 & {W}_{1}^{2} & 0 & 0 \\ 0 & 0 & ⋱ & 0 \\ 0 & 0 & 0 & {W}_{1}^{K}\end{matrix} ] ,$$
where W₁¹, W₁² . . . W₁^{K} are targeting wideband and/or long term channel properties for K closely spaced antenna groups, and
the sub-band short-term precoder is in the form of a second matrix W₂ having a form of
$${W}_{2} = [ \begin{matrix}{W}_{2}^{1} \\ {W}_{2}^{2} \\ ⋮ \\ {W}_{2}^{K}\end{matrix} ]$$
where W₂¹, W₂² . . . W₂^{K} are targeting frequency-selective and/or short term channel properties,
wherein a final precoder W is determinable according to
W=W₁W₂.

9. The apparatus according to claim 1, wherein
the closely spaced antenna group comprises at least one of a uniform linear antenna array with a specific number of elements or a cross polarized antenna array with a specific number of elements,
at least one closely spaced antenna group is assigned to one transmit point, and
the transmit point is one of a macro cell communication network control element or of a remote radio head linked to the macro cell communication network control element.

10. The apparatus according to claim 1, wherein the apparatus is comprised in a communication network element, in particular a user equipment.

11. A method comprising
receiving antenna information, the antenna information comprising information indicating a grouping of one or more antenna in at least one closely spaced antenna group of one or more transmit points,
estimating channels based on the received antenna port configuration data,
selecting at least one of a precoding codeword and an amplitude weight parameter for each of the at least one closely spaced antenna group,
determining information related to at least one of a sub-band precoder and a transmit point related combiner, and reporting results of the selecting and the determining.

12. The method according to claim 11, wherein
the antenna information further comprises antenna port configuration data of the at least one closely spaced antenna group of the one or more transmit points, and wherein the information indicating the grouping in the at least one closely spaced antenna group includes, for each of the at least one closely spaced antenna group, antenna array block size indication and information on assigned channel state information reference signal ports.

13. The method according to claim 11, wherein
the antenna information further comprises an identification of an antenna array type of each of the at least one closely spaced antenna group as being one of a uniform linear array type or a cross polarized array type.

14. The method according to claim 11, wherein
the amplitude weight parameter comprises one of an average cell gain parameter proportional to a pathloss experienced towards each of the at least one closely spaced antenna group, or a relative pathloss vector.

15. The method according to claim 11, wherein
the determining of information related to at least one of the sub-band precoder and the transmit point related combiner further comprises one of
computing at least one of the sub-band precoder and the transmit point related combiner for each of the at least one closely spaced antenna group by determining independently per transmit point beam selectors and co-phasing terms and transmit point related combiners, or
searching in a joint codebook and selecting a corresponding codeword in the joint codebook for identifying at least one of a suitable sub-band precoder and transmit point related combiner.

16. The method according to claim 15, wherein the transmit point related combiner comprises at least one of an intra-transmission point combiner and an inter-transmission point combined.

17. The method according to claim 11, wherein the reporting of the results of the computing and the determining further comprises
sending an index related to a wide-band long-term precoder based on the selected at least one of the precoding codeword and the amplitude weight parameter or an index from a codebook related to the amplitude weight parameter, and an index related to a sub-band short-term precoder based on
one of
an index per closely spaced antenna group of at least one of computed sub-band precoders and transmit point related combiners, or
a selected codeword of a joint codebook for identifying at least one of a suitable sub-band precoder and transmit point related combiner.

18. The method according to claim 17, wherein the wide-band long-term precoder is in the form of a first matrix W₁ having a block diagonal structure, wherein each block being mapped to the array size of a corresponding closely spaced antenna group, the first matrix W₁ having a form of
$${W}_{1} = [ \begin{matrix}{W}_{1}^{1} & 0 & 0 & 0 \\ 0 & {W}_{1}^{2} & 0 & 0 \\ 0 & 0 & ⋱ & 0 \\ 0 & 0 & 0 & {W}_{1}^{K}\end{matrix} ] ,$$
where W₁¹, W₁² . . . W₁^{K} are targeting wideband and/or long term channel properties for K closely spaced antenna groups, and
the sub-band short-term precoder is in the form of a second matrix W₂ having a form of
$${W}_{2} = [ \begin{matrix}{W}_{2}^{1} \\ {W}_{2}^{2} \\ ⋮ \\ {W}_{2}^{K}\end{matrix} ]$$
where W₂¹, W₂² . . . W₂^{K} are targeting frequency-selective and/or short term channel properties,
wherein a final precoder W is determinable according to
W=W₁W₂.

19. The method according to claim 11, wherein
the closely spaced antenna group comprises at least one of a uniform linear antenna array with a specific number of elements or a cross polarized antenna array with a specific number of elements,
at least one closely spaced antenna group is assigned to one transmit point, and
the transmit point is one of a macro cell communication network control element or of a remote radio head linked to the macro cell communication network control element.

20. The method according to claim 11, wherein the method is implemented in a communication network element, in particular a user equipment.

21. An apparatus comprising
a signaling processing portion configured to initiate transmission of antenna information to a communication network element, the antenna information comprising information indicating a grouping of one or more antenna in at least one closely spaced antenna group of one or more transmit points,
a receiving processing portion configured to receive processing results from the communication network element, the processing results comprising
at least one of an index of precoding codewords and an index of an amplitude weight parameter for each of the at least one closely spaced antenna group, and
at least one of an index of a sub-band precoder and an index of a transmit point related combiner, and
a processing portion configured to process the received processing results and to compute a final precoder on the basis the received processing results.

22. The apparatus according to claim 21, wherein
the antenna information further comprises antenna port configuration data of the at least one closely spaced antenna group of the one or more transmit points, and wherein the information indicating the grouping in the at least one closely spaced antenna group includes, for each of the at least one closely spaced antenna group, antenna array block size indication and information on assigned channel state information reference signal ports.

23. The apparatus according to claim 21, wherein the antenna information further comprises an identification of an antenna array type of each of the at least one closely spaced antenna group as being one of a uniform linear array type or a cross polarized array type.

24. The apparatus according to claim 21, wherein
the amplitude weight parameter comprises one of an average cell gain parameter proportional to a pathloss experienced by the communication network element towards each of the at least one closely spaced antenna group, or a relative pathloss vector.

25. The apparatus according to claim 21, wherein the receiving processing portion is further configured to receive, as the processing results,
an index related to a wide-band long-term precoder based on the selected at least one of the precoding codeword and the amplitude weight parameter or an index from a codebook related to the amplitude weight parameter, and an index related to a sub-band short-term precoder based on one of
an index per closely spaced antenna group of at least one of computed sub-band precoders and transmit point related combiners, or
a selected codeword of a joint codebook for identifying at least one of a suitable sub-band precoder and transmit point related combiner.

26. The apparatus according to claim 21, wherein the processing portion is further configured to compute the final precoder including a sub-band short-term precoder which comprises at least one of an intra-transmission point combiner and an inter-transmission point combined.

27. The apparatus according to claim 25, wherein the wide-band long-term precoder is in the form of a first matrix W₁ having a block diagonal structure, wherein each block being mapped to the array size of a corresponding closely spaced antenna group, the first matrix W₁ having a form of
$${W}_{1} = [ \begin{matrix}{W}_{1}^{1} & 0 & 0 & 0 \\ 0 & {W}_{1}^{2} & 0 & 0 \\ 0 & 0 & ⋱ & 0 \\ 0 & 0 & 0 & {W}_{1}^{K}\end{matrix} ] ,$$
where W₁¹, W₁² . . . W₁^{K} are targeting wideband and/or long term channel properties for K closely spaced antenna groups, and
the sub-band short-term precoder is in the form of a second matrix W₂ having a form of
$${W}_{2} = [ \begin{matrix}{W}_{2}^{1} \\ {W}_{2}^{2} \\ ⋮ \\ {W}_{2}^{K}\end{matrix} ]$$
where W₂¹, W₂² . . . W₂^{K} are targeting frequency-selective and/or short term channel properties, and
wherein the final precoder W is
W=W₁W₂.

28. The apparatus according to claim 21, wherein
the closely spaced antenna group comprises at least one of a uniform linear antenna array with a specific number of elements or a cross polarized antenna array with a specific number of elements,
at least one closely spaced antenna group is assigned to one transmit point, and
the transmit point is one of a macro cell communication network control element or of a remote radio head linked to the macro cell communication network control element.

29. The apparatus according to claim 21, wherein the apparatus is comprised in a communication network control element acting as a scheduler element, in particular an evolved node B.
